(19) United States
(12) Patent Application Publication
(10) Pub. No.: US 2026/0344161 A1
(43) Pub. Date: Oct. 29, 2026

(54) LIGHT SOURCE MODULE, LIGHTING SYSTEM AND LIGHTING FIXTURE

(71) Applicants: SUZHOU OPPLE LIGHTING CO., LTD., Suzhou City (CN); OPPLE LIGHTING CO., LTD., Shanghai (CN)

(72) Inventor: Changrong ZHU, Suzhou City (CN)

(73) Assignees: SUZHOU OPPLE LIGHTING CO., LTD., Suzhou City (CN); OPPLE LIGHTING CO., LTD., Shanghai (CN)

(21) Appl. No.: 19/686,989

(22) Filed: May 25, 2026

Related U.S. Application Data
(63) Continuation of application No. PCT/CN2024/133938, filed on Nov. 22, 2024.

(30) Foreign Application Priority Data
Nov. 23, 2023 (CN) 202311578609.2
Nov. 23, 2023 (CN) 202323178546.X

(51) Int. Cl. H10H 29/851; H10H 29/853

(52) U.S. Cl. CPC H10H 29/8514; H10H 29/8512; H10H 29/853

(57) ABSTRACT

A light source module, a lighting system, and a lighting fixture are provided. The light source module includes first, second, third, and fourth electrically independent light-emitting units. The first, second, and third light-emitting units are configured to emit blue-green, yellow-orange, and orange-red light, respectively, and the fourth light-emitting unit is configured to emit blue light. The emitted light is characterized by predetermined spectral distributions and chromaticity ranges. White light generated by mixing light emitted from the four light-emitting units may have an adjustable correlated color temperature, a low color deviation from a blackbody radiation locus, and a high color rendering index. A driving circuit independently controls power supplied to the light-emitting units. The light source module may be incorporated into a lighting system or a lighting fixture.

### CROSS-REFERENCE

This disclosure is based upon and claims the priority of PCT patent disclosure No. PCT/CN2024/133938 filed on Nov. 22, 2024, which claims priority to the Chinese patent disclosure No. 202311578609.2 filed on Nov. 23, 2023 and the Chinese patent disclosure No. 202323178546.X filed on Nov. 23, 2023, the entire contents of which are hereby incorporated by reference herein for all purposes.

### TECHNICAL FIELD

The present disclosure relates to a light source module, a lighting system and a lighting fixture.

### BACKGROUND

In the lighting field, because of the low power consumption and high luminous efficacy of the light-emitting diode (LED), LED has rapidly replaced traditional light source and has been applied to various light-emitting devices, such as indoor and outdoor lighting, intelligent lighting, plant lighting, vehicle lighting, and indoor and outdoor display lighting.

### SUMMARY

The present disclosure provides a light source module, a lighting system, and a lighting fixture.

In some examples, the light source module includes a first light-emitting unit, a second light-emitting unit, a third light-emitting unit, and a fourth light-emitting unit that are electrically independent of one another. The first light-emitting unit is configured to emit blue-green light, the second light-emitting unit is configured to emit yellow-orange light, the third light-emitting unit is configured to emit orange-red light, and the fourth light-emitting unit is configured to emit blue light. The emitted light of the light-emitting units is characterized by predetermined spectral distributions and chromaticity ranges.

In some examples, white light is generated by mixing light emitted from the first, second, third, and fourth light-emitting units. The generated white light may have an adjustable correlated color temperature over a broad range, a low color deviation relative to a blackbody radiation locus, and a high color rendering index. In some embodiments, the generated white light exhibits enhanced color fidelity and color gamut characteristics and may simulate one or more target spectra.

In some examples, the fourth light-emitting unit includes a plurality of blue light-emitting diode chips having different peak wavelengths. In some embodiments, the light source module is implemented as an encapsulated chip or includes a light source board on which the light-emitting units are disposed.

The present disclosure further provides a lighting system including the light source module and a driving circuit configured to independently control electrical power supplied to the light-emitting units. The present disclosure further provides a lighting fixture including the light source module and/or the lighting system.

It is to be understood that both the foregoing general description and the following detailed description are exemplary and explanatory only and are not restrictive of the present disclosure.

### BRIEF DESCRIPTION OF DRAWINGS

FIG. 1 is a schematic structural diagram of a light source module according to an example of the present disclosure.

FIG. 2 is a color point distribution diagram of the first light-emitting unit, the second light-emitting unit, and the third light-emitting unit in the light source module according to an example of the present disclosure on the 1931-CIE chromaticity diagram.

FIG. 3 is a spectral energy distribution diagram of the first light-emitting unit, the second light-emitting unit, and the third light-emitting unit in the light source module according to an example of the present disclosure.

FIG. 4 is an emission spectrum curve comparison diagram of white light example a emitted by the light source module according to an example of the present disclosure and a standard blackbody radiation light source (B27).

FIG. 5 is an emission spectrum curve comparison diagram of white light example b emitted by the light source module according to an example of the present disclosure and a standard blackbody radiation light source (B30).

FIG. 6 is an emission spectrum curve comparison diagram of white light example c emitted by the light source module according to an example of the present disclosure and a standard D40 light source.

FIG. 7 is an emission spectrum curve comparison diagram of white light example d emitted by the light source module according to an example of the present disclosure and a standard D50 light source.

FIG. 8 is an emission spectrum curve comparison diagram of white light example e emitted by the light source module according to an example of the present disclosure and a standard D57 light source.

FIG. 9 is an emission spectrum curve comparison diagram of white light example f emitted by the light source module according to an example of the present disclosure and a standard D65 light source.

FIG. 10 is an emission spectrum curve comparison diagram of white light example g emitted by the light source module according to an example of the present disclosure and a standard blackbody radiation light source.

FIG. 11 is an emission spectrum curve comparison diagram of white light example h emitted by the light source module according to an example of the present disclosure and a standard blackbody radiation light source.

FIG. 12 is an emission spectrum curve comparison diagram of white light example i emitted by the light source module according to an example of the present disclosure and a standard D series light source.

FIG. 13 is an emission spectrum curve comparison diagram of white light example j emitted by the light source module according to an example of the present disclosure and a standard D series light source.

FIG. 14a, FIG. 14b, FIG. 14c, FIG. 14d, FIG. 14e, and FIG. 14f are schematic diagrams of encapsulation structures of light source modules according to other examples of the present disclosure.

FIG. 15 is a schematic structural diagram of a lighting system according to an example of the present disclosure.

FIG. 16 is a schematic structural diagram of a lighting fixture according to an example of the present disclosure.

FIG. 17 is a schematic structural diagram of a light source module according to another example of the present disclosure.

### DETAILED DESCRIPTION OF EXAMPLES

The following further describes the light source module, the lighting system, and the lighting fixture proposed in the present disclosure in detail with reference to the accompanying drawings and some examples consistent with the present disclosure.

As the performance and cost of LED lighting continue to improve, the market penetration rate has also been raised in synchronization. At the same time, user's requirement for the light quality of lighting has become higher and higher. From the perspective of color rendering, it has progressed from the earliest color rendering index of 70 to a color rendering index of 80, 90, or even 95, 97 or above. In terms of the spectrum trend, it is gradually approaching the natural light spectrum, supplementing or eliminating specific visible light bands to improve its degree of fitting with the natural light spectrum. In addition, dual color temperature dimming is superimposed to realize lighting scenes within different color temperature ranges, so as to form dimming and toning lighting products with high light quality.

However, the general single color temperature or dual color temperature white light dimming method has a limited adjustable color temperature range, which is determined by the color temperatures of the two white light chips used. In addition, because its dimming trajectory is a connecting line between two color temperature points on the CIE-1931 chromaticity diagram, when adjusted to an intermediate color temperature, because its color point has a relatively large difference from the blackbody radiation line, its light color and spectrum have a relatively obvious deviation from a standard light source of the same color temperature. Furthermore, the light color quality of the intermediate color temperature is also sacrificed, and there is a relatively large difference compared with the single white light full-spectrum of the same color temperature, especially in R9 and R12 of the color rendering index. Generally, in order to improve the problem of large color deviation at the intermediate color temperature, two white light chips with a smaller color temperature difference may be used for dimming, or the color point specifications of the two white light chips may be adjusted to ensure that when adjusted to the intermediate color temperature, its color point falls on the target value to reduce the color deviation. Of these two approaches, one further reduces the adjustable color temperature range of the white light, and the other ensures the light color quality of the intermediate color temperature but at the same time sacrifices the light color effects of the highest and lowest color temperatures. Regardless of the specifications of the white light spectrum used, even if a full-spectrum white light chip is used, there exist the above-mentioned problems of the limited adjustable color temperature range and the relatively large color deviation that result in degradation of light quality.

In addition, in order to further expand the overall white light color temperature range, the red, green and blue three primary colors are generally superimposed on the basis of the original single color temperature or dual color temperature white light chip for dimming and color tuning, that is, an RGBW or RGBCW multi-color light mixing manner. The light mixing manner is as follows: when the target color temperature value is within the single color temperature or dual color temperature white light range, the main entities participating in the light mixing are these white light chips; and when the target color temperature value exceeds the range, the red, green and blue three primary colors are used for light mixing, or color compensation is used to obtain the white light of the required target color temperature. However, regardless of which manner is adopted, in terms of the color rendering performance of the white light obtained by such light mixing, only within the color temperature range covered by the existing white light chips can the color rendering be guaranteed. When this range is exceeded, because the LEDs used for the three primary colors mainly include single-wavelength LED chips, and the full-width half-maximum (FWHM) of each monochromatic color is relatively narrow, the continuity of the spectral of the white light obtained by the light mixing is poor, and it cannot be guaranteed that the color rendering index outside the color temperature range of the white light chips remains at a relatively high level.

With the improvement of people's living standards, the requirements for lighting are more diversified, and how to provide a lighting device that can completely simulate the color temperature variation of outdoor natural light and have light quality comparable to natural light has become an issue that needs to be improved urgently.

An example of the light source module of the present disclosure is a light-mixing LED encapsulated chip. The encapsulation form may be a PLCC surface mount encapsulation, a ceramic surface mount encapsulation, a CSP encapsulation, a multi-in-one single-body surface mount encapsulation, or a COB chip integrated encapsulation, and the present disclosure does not limit this.

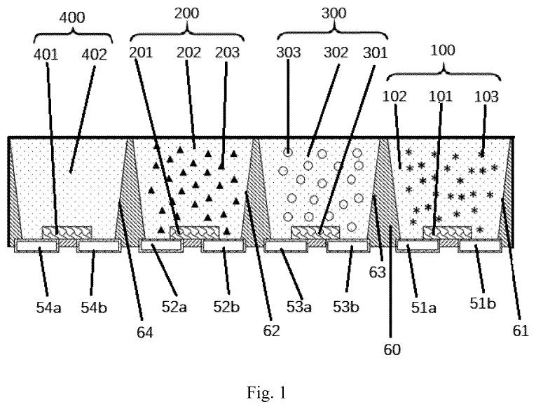

The structure of an example of the present disclosure is as illustrated by FIG. 1. The light source module (1) includes a main body (60) and a plurality of light-emitting units disposed on the main body (60) and spaced apart from each other, which are, a first light-emitting unit (100), a second light-emitting unit (200), a third light-emitting unit (300), and a fourth light-emitting unit (400). Each of the light-emitting units (100, 200, 300, 400) includes a light-emitting source (101, 201, 301, 401) and an encapsulation body (102, 202, 302, 402) covering thereon. The light-emitting sources (101, 201, 301, 401) are LED chips (LED Chip), each of which includes upright or flip-chip type, and each of which can be a single LED chip, or a plurality of LED chips connected together in series, parallel, or series-parallel manner. In this example, in order to accommodate the encapsulation bodies (102, 202, 302, 402), the main body (60) is a plastic bracket, in which a plurality of receiving grooves (61, 62, 63, 64) are provided. The material of the plastic bracket may be any one of PPA, PCT, and EMC. Each light-emitting source (101, 201, 301, 401) is respectively disposed in the receiving groove (61, 62, 63, 64), and each has a pair of pins (51a, 51b, 52a, 52b, 53a, 53b, 54a, 54b), wherein the pins (51a, 51b, 52a, 52b, 53a, 53b, 54a, 54b) are electrically isolated from each other. The encapsulation bodies (102, 202, 302, 402) are made of silicone resin, epoxy resin, or a combination thereof, and are respectively filled into the receiving grooves (61, 62, 63, 64) and cover each LED chip (101, 201, 301, 401), so as to ensure the electrical isolation between each light-emitting unit (100, 200, 300, 400).

In this example, a light-mixing scheme with multiple light sources is adopted, in which the first light-emitting unit 100, the second light-emitting unit 200, the third light-emitting unit 300, and the fourth light-emitting unit 400 respectively emit blue-green light, yellow-orange light, orange-red light, and blue light, and the combined light emitted by each light-emitting unit can form white light. Among them, the first light-emitting unit 100, the second light-emitting unit 200, and the third light-emitting unit 300 employ phosphor excitation schemes, in which the light-emitting source excites the phosphor to realize light mixing, so as to form the light emitted by the light-emitting unit. The fourth light-emitting unit 400 employs a phosphor-free scheme, specifically as follows.

The fourth light-emitting unit 400 includes a fourth light-emitting source 401 and a fourth encapsulation body 402. The fourth light-emitting source 401 is placed at the bottom of the fourth receiving groove 64, and is electrically connected to the outside through two pins (54a, 54b). The fourth encapsulation body 402 fills the fourth receiving groove 64 and covers the fourth light-emitting source 401.

The fourth light-emitting source 401 is an LED chip combination, including two or more blue LED chips with different peak wavelengths, and the blue LED chips are connected in series or parallel. The blue LED chip refers to a LED chip that emit blue light with a peak wavelength in the range of 430 nm to 475 nm. The reason for selecting multiple different blue LED chips to be combined to form the fourth light-emitting source 401 is that phosphors generally have a wider distribution in terms of full-width half-maximum (FWHM), while the monochromatic LED chip has a narrower FWHM. In this example, although no phosphor is added in the fourth light-emitting unit 400, in the case where the FWHM of monochromatic LED chip is narrower, selecting chips with different peak wavelengths can form a superposition in the blue light band, thereby making the overall energy distribution in the blue light region more uniform, and the color rendering also better. In this example, the difference in peak wavelengths between two LED chips is greater than or equal to 10 nm, which can ensure a wider energy distribution in the blue light region. In an optional scheme, the blue LED chips with peak wavelengths in the range of 430 nm to 475 nm are divided into three types, namely, a first blue LED chip with a peak wavelength of 430 nm to 445 nm; a second blue LED chip with a peak wavelength of 445 nm to 460 nm; and a third blue LED chip with a peak wavelength of 460 nm to 475 nm, and the peak wavelength difference between any two of these three types is ensured to be greater than or equal to 10 nm. The fourth light-emitting source 401 includes at least the first blue LED chip and the third blue LED chip among these two types of chips, or simultaneously includes a combination of all the three types of chips, which are the first blue LED chip, the second blue LED chip, and the third blue LED chip. At the same time, because the first light-emitting unit 100, the second light-emitting unit 200, and the third light-emitting unit 300 each employs the form of blue LED chip exciting phosphor, the first light-emitting source 101, the second light-emitting source 201, and the third light-emitting source 301 are also selected from among the first blue LED chip, the second blue LED chip, and the third blue LED chip. In response to that the fourth light-emitting source 401 selects two of the above three, the first light-emitting source 101, the second light-emitting source 201, and the third light-emitting source 301 may select the remaining one. In response to that the first light-emitting source 101 selects a combination of all three types of chips, the first light-emitting source 101, the second light-emitting source 201, and the third light-emitting source 301 may arbitrarily select any one of the three types of chips. In this example, the first light-emitting source 101 selects a combination of the first blue LED chip and the third blue LED chip, and the second light-emitting source 201 and the third light-emitting source 301 are selected as the second blue LED chip.

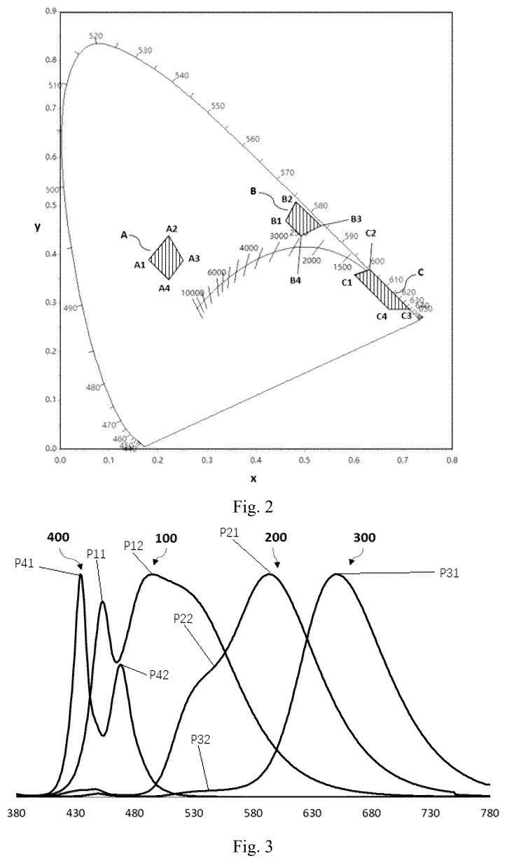

The spectral energy distribution of the light emitted by the fourth light-emitting unit 400 formed by the combination of blue chips is shown as a curve 400 in FIG. 3. FIG. 3 is a relative spectral intensity diagram, in which each curve has been normalized, and each point on the curve represents the energy magnitude at a certain wavelength on the horizontal axis. As can be seen in the figure, the curve 400 includes at least two spectral emission peaks, a first peak wavelength P41 is located at 430 nm to 445 nm, a second peak wavelength P42 is located at 460 nm to 480 nm, and the spectral intensity at the second peak wavelength P42 is 40% to 80% of the spectral intensity at the first peak wavelength P41.

The first light-emitting unit 100 includes a first light-emitting source 101 and a first encapsulation body 102. The first light-emitting source 101 is placed at the bottom of the first receiving groove 61, and is electrically connected to the outside through two pins (51a, 51b). The first encapsulation body 102 fills the first receiving groove 61 and covers the first light-emitting source 101. The first light-emitting source 101 is a blue LED that emits blue light with a peak wavelength in the range of 445 nm to 460 nm. The first encapsulation body 102 contains a first phosphor body 103, and the first phosphor body 103 includes at least one blue-green phosphor with a peak wavelength of 485 nm to 515 nm and at least one yellow-green phosphor with a peak wavelength of 500 nm to 580 nm. In order to obtain a wider FWHM, the first phosphor body 103 simultaneously contains two phosphors with different peak wavelengths, that are blue-green phosphor and yellow-green phosphor. Of course, the blue-green phosphor and the yellow-green phosphor each mentioned here is not limited to including only one chemical composition; each of them may still be a mixed phosphor, that is, more than one phosphor may be mixed to finally form the blue-green phosphor and yellow-green phosphor we require. The blue-green phosphor may be selected from (Ba, Sr)Si₂N₂O₂:Eu. The yellow-green phosphor may be selected from any one or a combination of multiple of (Lu, Yb, Tb)₃(Al, Ga)₅O₁₂:Ce, Ga—Y₃Al₅O₁₂:Ce, and Y₃(Al, Ga)₅O₁₂:Ce.

The blue LED chip serving as the first light-emitting source 101 is disposed in the receiving groove 61. After its emitted light excites the first phosphor body 103, the spectral energy distribution of the light emitted by the first light-emitting unit 100 is shown as the curve 100 in FIG. 3. FIG. 3 is a relative spectral intensity diagram, in which each curve has been normalized, and each point on the curve represents the energy magnitude at a certain wavelength on the horizontal axis. As illustrated by FIG. 3, the spectral curve of the light emitted by the first light-emitting unit 100 includes at least two spectral emission peaks, a first peak wavelength P11 is located at 445 nm to 460 nm, a second peak wavelength P12 is located at 480 nm to 520 nm, and the spectral intensity at the second peak wavelength P12 is 100% to 150% of the spectral intensity at the first peak wavelength P11. The light color of the light emitted by the first light-emitting unit 100 is blue-green, and is located within a quadrilateral region defined by the four points A1(0.18, 0.39), A2(0.22, 0.44), A3(0.25, 0.39), and A4(0.22, 0.35) on the 1931-CIE chromaticity diagram, i.e., the region A marked in FIG. 2.

The second light-emitting unit 200 includes a second light-emitting source 201 and a second encapsulation body 202. The second light-emitting source 201 is placed at the bottom of the second receiving groove 62, and is electrically connected to the outside through two pins (52a, 52b). The second encapsulation body 202 fills the second receiving groove 62 and covers the second light-emitting source 201. The second light-emitting source 201 is a blue LED that emits blue light with a peak wavelength in the range of 445 nm to 460 nm. The second encapsulation body 202 contains a second phosphor body 203, and the second phosphor body 203 includes at least one type of yellow phosphor with a peak wavelength of 550 nm to 580 nm and at least one red/orange phosphor with a peak wavelength of 580 nm to 620 nm. The yellow phosphor may be selected from any two or more combinations of (Lu, Yb, Tb)₃(Al, Ga)₅O₁₂:Ce, Ga—Y₃Al₅O₁₂:Ce, and Y₃(Al, Ga)₅O₁₂:Ce. The orange/red phosphor may be selected from any one or a combination of several of CaAlSiN₃:Eu, (Ca, Sr)AlSiN₃:Eu, (Ba, Sr, Ca, Mg)₂Si₅N₈:Eu, K₂SiF₆:Mn⁴⁺, K₂GeF₆:Mn⁴⁺, and K₂TiF₆:Mn⁴⁺. After the second light-emitting source 201 excites the second phosphor body 203, the light emitted by the second light-emitting unit 200 includes at least two spectral emission peaks. As illustrated by FIG. 3, a first peak wavelength P21 is located at 585 nm to 620 nm, a second peak wavelength P22 is located at 550 nm to 580 nm, and the spectral intensity at the second peak wavelength P22 is 40% to 70% of the spectral intensity at the first peak wavelength P21, with a spectral half-width (FWHM) of 80 nm to 120 nm. Its spectral energy distribution is shown as the curve 200 in FIG. 3. The light color of the light emitted by the second light-emitting unit 200 is yellow-orange, located within a quadrilateral region defined by the four points B1(0.46, 0.47), B2(0.48, 0.51), B3(0.53, 0.46), and B4(0.49, 0.44) on the 1931-CIE chromaticity diagram, i.e., the region B marked in FIG. 2. Because most of the energy emitted by the second light-emitting source 201 is converted into yellow-orange light by the second phosphor body 203, the blue light content of the light emitted by the second light-emitting unit 200 is less than 10%. The blue light content being less than 10% means that, in the light emitted by the light-emitting unit, the proportion of energy in the blue light band of 440 nm to 480 nm region in the total energy is less than 10%.

The third light-emitting unit 300 includes a third light-emitting source 301 and a third encapsulation body 302. The third light-emitting source 301 is placed at the bottom of the third receiving groove 63, and is electrically connected to the outside through two pins (53a, 53b). The third encapsulation body 302 fills the third receiving groove 63 and covers the third light-emitting source 301. The third light-emitting source 301 is a blue LED that emits blue light with a peak wavelength in the range of 445 nm to 460 nm. The third encapsulation body 302 contains a third phosphor body 303, and the third phosphor body 303 includes at least one yellow-green phosphor with a peak wavelength of 520 nm to 580 nm and at least one red phosphor with a peak wavelength of 630 nm to 680 nm. The third phosphor body 303 needs to simultaneously include two phosphors, which are the yellow-green phosphor and the red phosphor. Of course, each of these two phosphors may also be a mixed phosphor. The yellow-green phosphor may be selected from any one or a combination of multiple of (Lu, Yb, Tb)₃(Al, Ga)₅O₁₂:Ce, Ga—Y₃Al₅O₁₂:Ce, and Y₃(Al, Ga)₅O₁₂:Ce. The red phosphor may be selected from any one or a combination of several of CaAlSiN₃:Eu, (Ca, Sr)AlSiN₃:Eu, (Ba, Sr, Ca, Mg)₂Si₅N₈:Eu, K₂SiF₆:Mn⁴⁺, K₂GeF₆:Mn⁴⁺, and K₂TiF₆:Mn⁴⁺. After the third phosphor body 303 is excited by the third light-emitting source 301, the light emitted by the third light-emitting unit 300 includes at least two spectral emission peaks, with a first peak wavelength P31 located at 630 nm to 680 nm, a second peak wavelength P32 located at 550 nm to 580 nm, and the spectral intensity at the second peak wavelength P32 is 0 to 40% of the spectral intensity at the first peak wavelength P31, with a spectral half-width (FWHM) of 70 nm to 100 nm. Its spectral energy distribution is shown as the curve 300 in FIG. 3. The light color of the light emitted by the third light-emitting unit 300 is orange-red, and is located within a quadrilateral region defined by the four points C1(0.60, 0.36), C2(0.63, 0.37), C3(0.71, 0.29), and C4(0.67, 0.29) on the 1931-CIE chromaticity diagram, i.e., the region C marked in FIG. 2. Because most of the energy emitted by the third light-emitting source 301 is converted into orange-red light by the second phosphor body 303, the blue light content of the light emitted by the third light-emitting unit 300 is less than 5%. The blue light content being less than 5% means that, in the light emitted by the light-emitting unit, the proportion of energy in the blue light band of 440 nm to 480 nm region in the total energy is less than 5%.

It is well known that three primary colors can be mixed to form white light. In previous schemes, white light has been formed by mixing RGB three colors. In this example, the existing RGB scheme is optimized by selecting different light colors. The first light-emitting unit 100 emits blue-green light, the second light-emitting unit 200 emits orange-yellow light, the third light-emitting unit 300 emits orange-red light, and the fourth light-emitting unit 400 emits blue light. In response to that the light emitted by these four is synthesized into white light, full-spectrum white light can be obtained. The full-spectrum white light proposed in the present disclosure is achieved by simulating a target spectrum. In response to that the target color temperature is lower than 4000K, the emission spectrum of the light source module 1 takes the blackbody radiation spectrum as the target spectrum. In response to that the target color temperature is above 4000K, the emission spectrum of the light source module 1 takes the simulated daylight spectrum as the target spectrum. The daylight spectrum described in the present disclosure is the relative spectral power distribution of the D-series standard illuminants specified by the International Commission on Illumination (CIE), such as the D50, D57, D65 standard light sources, etc. In addition, the blackbody radiation spectrum (B) at different color temperatures (T) conforms to the following relationship:

$${B}_{λ} ( T ) = \frac{2 {hc}^{2}}{{λ}^{5}} \frac{1}{{e}^{\frac{hc}{{KT}_{B} λ}} - 1}$$

Where T represents color temperature, h is Planck's constant, c is the speed of light (3×10\hat{ }8 m/s), K is the Boltzmann constant, TB is the absolute temperature of the blackbody, and λ is the radiation wavelength.

In order to evaluate the simulation matching degree between the white light spectrum obtained in the example and the target spectrum, and given that there is currently no relevant evaluation standard issued by an authoritative organization, the spectral matching degree adopted in the present disclosure, namely, the evaluation method of spectral similarity (SS, Spectral Similarity), refers to the average spectral difference (ASD, Average Spectral Difference) published. The reference light source spectrum at different color temperatures adopted therein are similar to the TM-30 standard issued by the Illuminating Engineering Society of North America (IES), that is, in response to that the color temperature is above 5000K, the reference spectrum is based on the D-series standard illuminants; in response to that the color temperature is below 4000K, it is based on the spectrum emitted by the blackbody radiation light source; and in response to that the color temperature is between 4000K and 5000K, the spectrum emitted by a mixed light source of the 4000K blackbody radiation light source and the D50 standard illuminant is used as the reference. In addition, considering the band distribution of the human eye's sensitive visual response, the spectral deviation evaluation range is limited to between 425 nm and 690 nm. The specific calculation method is shown below:

$$ASD = \frac{{\sum }_{λ = 425}^{λ = 690} \vert \frac{{ϕ}_{ref} - ϕ}{{ϕ}_{ref}} \vert}{266} * 100 \%$$

$$SS = 1 - ASD$$

Where φref is the relative intensity of the reference light source, q is the relative intensity of the light source to be evaluated, and A is the wavelength.

By performing dimming control on the four light-emitting units respectively, white light of various different color temperatures can be obtained by mixing. In this example, the PWM signal is used as the control signal, the four-color light-emitting units are independently controlled through PWM dimming, and different duty ratios are applied to modulate the luminous power of each light-emitting unit so as to achieve the light mixing effect. Table 1 lists several examples in which the duty ratios of the PWM signal of the three light-emitting units is modulated under different conditions to obtain a general color temperature of the white light range from 2700K to 6500K. Table 1 shows the PWM duty ratio of each light-emitting unit, as well as the actual color temperature of the full-spectrum white light achieved by the light source module (1) through modulation of the PWM signals of the four light-emitting units, the color deviation (Duv) from the blackbody radiation line, the spectral similarity, the color rendering index (CRI), the color fidelity (Rf), the color gamut (Rg), and the special color rendering indices R1 to R15.

TABLE 1

| | a | b | c | d | e | f |
|---|---|---|---|---|---|---|
| First light-emitting | 15% | 18% | 23% | 25% | 25% | 25% |
| unit 100 | | | | | | |
| PWM duty ratio | | | | | | |
| Second light-emitting | 36% | 35% | 29% | 24% | 21% | 19% |
| unit 200 | | | | | | |
| PWM duty ratio | | | | | | |
| Third light-emitting | 45% | 39% | 28% | 20% | 17% | 14% |
| unit 300 | | | | | | |
| PWM duty ratio | | | | | | |
| Fourth light-emitting | 4% | 7% | 20% | 32% | 37% | 42% |
| unit 400 | | | | | | |
| PWM duty ratio | | | | | | |
| Correlated color | 2727 | 3001 | 4003 | 5019 | 5697 | 6513 |
| temperature | | | | | | |
| CCT (K) | | | | | | |
| Color deviation Duv | 0.0000 | 0.0001 | 0.0002 | 0.0000 | 0.0002 | 0.0002 |
| Spectral | 88% | 90% | 90% | 90% | 91% | 91% |
| similarity SS | | | | | | |
| Color fidelity Rf | 97 | 97 | 97 | 97 | 97 | 97 |
| Color gamut Rg | 100 | 100 | 100 | 101 | 101 | 101 |
| CRI (Ra) | 98.1 | 98.5 | 98.5 | 98.3 | 98.3 | 98.3 |
| R1 | 98 | 99 | 99 | 99 | 98 | 98 |
| R2 | 100 | 100 | 99 | 99 | 99 | 99 |
| R3 | 97 | 98 | 99 | 99 | 98 | 98 |
| R4 | 97 | 98 | 98 | 99 | 98 | 98 |
| R5 | 98 | 99 | 99 | 99 | 98 | 98 |
| R6 | 97 | 98 | 98 | 98 | 98 | 97 |
| R7 | 99 | 99 | 98 | 98 | 99 | 99 |
| R8 | 98 | 98 | 98 | 97 | 99 | 99 |
| R9 | 94 | 93 | 94 | 93 | 99 | 98 |
| R10 | 100 | 99 | 99 | 98 | 98 | 98 |
| R11 | 94 | 96 | 96 | 97 | 97 | 97 |
| R12 | 95 | 95 | 95 | 97 | 97 | 96 |
| R13 | 98 | 99 | 98 | 99 | 98 | 98 |
| R14 | 97 | 98 | 99 | 99 | 99 | 98 |
| R15 | 99 | 99 | 99 | 99 | 98 | 98 |

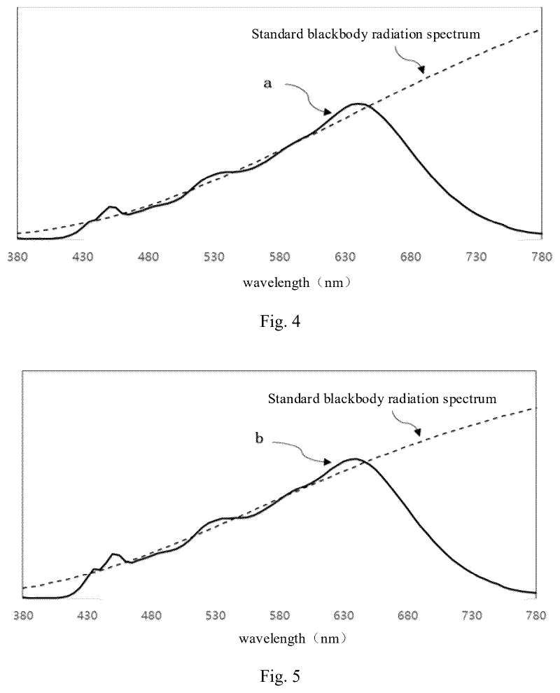

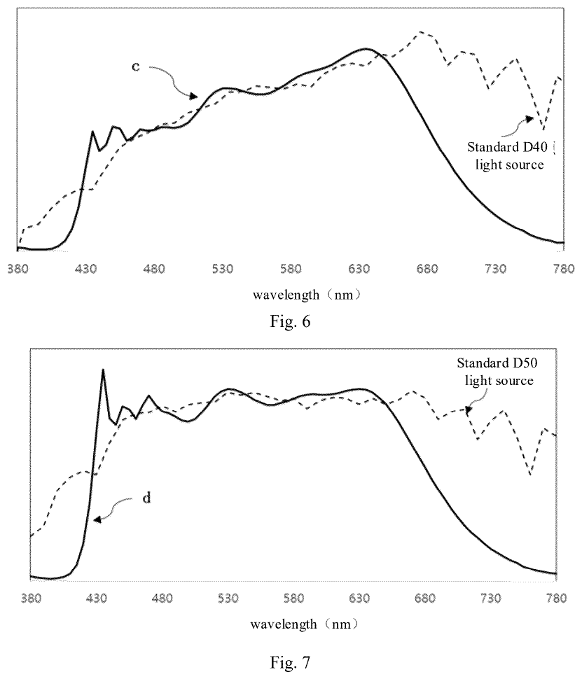

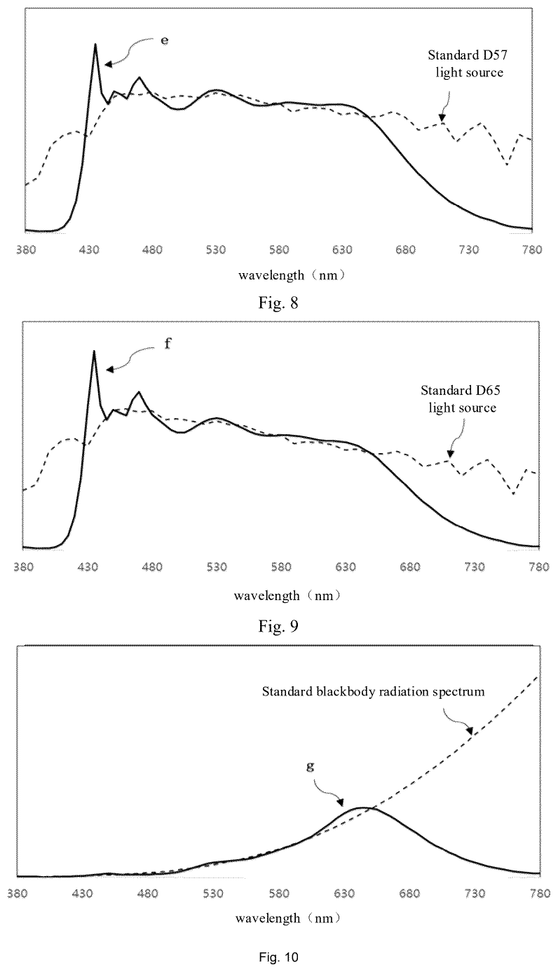

The examples a, b, c, d, e, and f in the table correspond to target color temperatures of 2700K, 3000K, 4000K, 5000K, 5700K, and 6500K, respectively. The target color temperature is the color temperature desired to be obtained. However, due to individual product differences, the actual values may slightly deviate at the determined target color temperature, and the color temperatures listed in the table are the actual measured color temperatures of each example. The spectral energy distribution of the full-spectrum white light obtained in each example and its comparison with the target spectrum are illustrated by FIG. 4 to FIG. 9. Among them, FIG. 4 is a comparison diagram of the emission spectrum curves of example a and the standard blackbody radiation light source (B27); FIG. 5 is a comparison diagram of the emission spectrum curves of example b and the standard blackbody radiation light source (B30); FIG. 6 is a comparison diagram of the emission spectrum curves of example c and the standard D40 light source; FIG. 7 is a comparison diagram of the emission spectrum curves of example d and the standard D50 light source; FIG. 8 is a comparison diagram of the emission spectrum curves of example e and the standard D57 light source; and FIG. 9 is a comparison diagram of the emission spectrum curves of example f and the standard D65 light source.

In addition to the data of the examples listed in Table 1, the color temperature of the white light obtainable by the light source module 1 proposed in the present disclosure has a wider range than the general white light color temperature range. Table 2 lists the example data of the light source module 1 in two ranges of color temperature of the white light from 1800K to 2700K and from 6500K to 20000K, including the control duty ratio of each channel and related light quality data.

TABLE 2

| | g | h | i | j |
|---|---|---|---|---|
| First light-emitting unit 200 PWM [symbol] | 3% | 10% | 23% | 20% |
| Second light-emitting unit 300 PWM duty ratio | 30% | 35% | 13% | 10% |
| Third light-emitting unit 400 PWM duty ratio | 67% | 55% | 10% | 6% |
| Fourth light-emitting unit 100 PWM duty ratio | 0% | 0% | 54% | 63% |
| Correlated color temperature CCT (K) | 1795 | 2313 | 10098 | 19878 |
| Color deviation Duv | −0.0002 | −0.0001 | 0.0003 | 0.0003 |
| Spectral similarity SS | 78% | 85% | 90% | 88% |
| Color fidelity Rf | 91 | 97 | 96 | 94 |
| Color gamut Rg | 104 | 101 | 100 | 99 |
| CRI (Ra) | 96.7 | 97.4 | 98.0 | 97.1 |
| R1 | 99 | 97 | 97 | 97 |
| R2 | 100 | 99 | 98 | 98 |
| R3 | 94 | 97 | 98 | 97 |
| R4 | 96 | 95 | 98 | 96 |
| R5 | 98 | 97 | 98 | 96 |
| R6 | 96 | 96 | 97 | 95 |
| R7 | 96 | 99 | 100 | 98 |
| R8 | 94 | 99 | 99 | 98 |
| R9 | 87 | 96 | 94 | 94 |
| R10 | 97 | 99 | 98 | 96 |
| R11 | 90 | 91 | 98 | 97 |
| R12 | 96 | 95 | 94 | 91 |
| R13 | 99 | 97 | 98 | 99 |
| R14 | 94 | 97 | 98 | 98 |
| R15 | 97 | 100 | 97 | 98 |

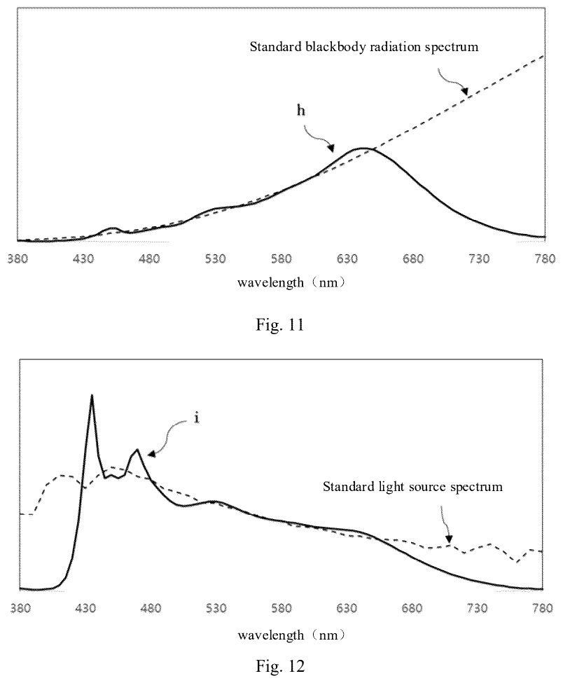

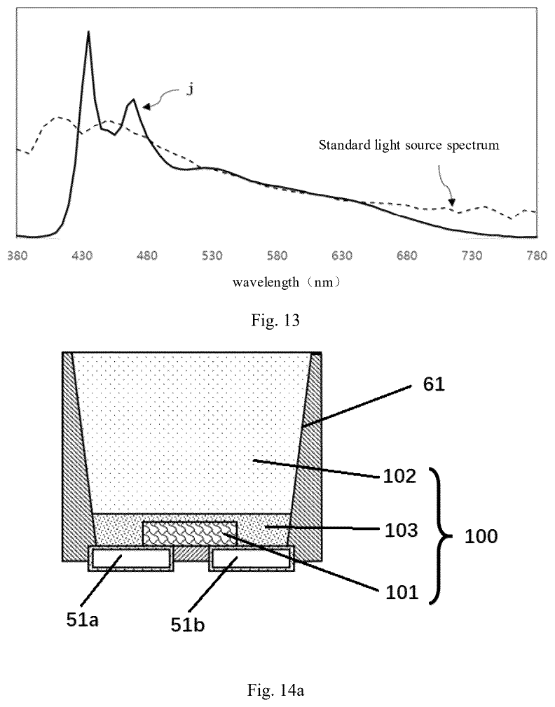

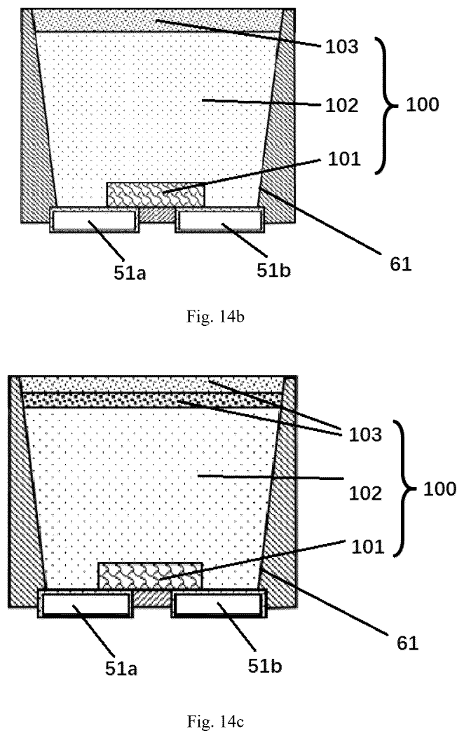

The spectral energy distribution of the full-spectrum white light obtained in each example listed in the table and its comparison with the target spectrum are illustrated by FIG. 10 to FIG. 13. Among them, FIG. 10 is a comparison diagram of the emission spectrum curves of example g and the standard blackbody radiation light source; FIG. 11 is a comparison diagram of the emission spectrum curves of example h and the standard blackbody radiation light source; FIG. 12 is a comparison diagram of the emission spectrum curves of example i and the standard D-series light source; and FIG. 13 is a comparison diagram of the emission spectrum curves of example j and the standard D-series light source.

As can be seen from Table 1 and Table 2, in this example, the full-spectrum white light emitted after the light mixing of the first light-emitting unit 100, the second light-emitting unit 200, the third light-emitting unit 300, and the fourth light-emitting unit 400 has a wide color temperature coverage range, which can be achieved from 1800K to 20000K, and the color deviation Duv from the blackbody radiation line is less than 0.003, ensuring that the light color of the entire light source module is more pure under any color temperature state. At the same time, the white light spectrum obtained has a high degree of spectral similarity with the target spectrum. In response to that the color temperature of the white light emitted by the light source module is 2300K to 20000K, the spectral similarity is greater than 85%, and in response to that the color temperature of the white light is 3000 K to 10000K, the spectral similarity is greater than 90%. Basically, in the adjustable color temperature range of the light source module, the white light spectrum reaches the level of full-spectrum. Here we list several existing LED light sources with a correlated color temperature of 4000K and calculate their SS values according to the above evaluation method, and take them as comparison reference values for the examples of the present disclosure. Among them, the existing conventional Ra80 white LED has a spectral similarity of 68%, the conventional Ra90 white LED has a spectral similarity of 78%, and the conventional Ra95 white LED has a spectral similarity of 81%. The spectral similarity of these existing products is significantly lower than that of the light source module 1 proposed in the present disclosure. In terms of color rendering, also due to its high spectral similarity, in response to that the color temperature of the white light emitted by the light source module is 1800K to 20000K, the color rendering index CRI is greater than 95, and in response to that the color temperature of the white light is 2300K to 10000K, the color rendering index CRI is greater than 97, with R1 to R15 all being greater than 90, the color fidelity Rf based on the TM-30 standard is greater than 95, and the color gamut Rg is from 98 to 102. In summary, the light source module 1 simultaneously has the advantages of a wide color temperature range, high spectral similarity, and good color rendering performance.

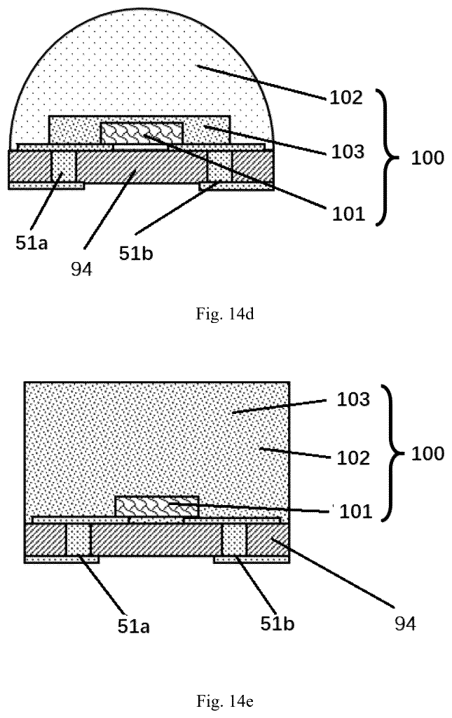

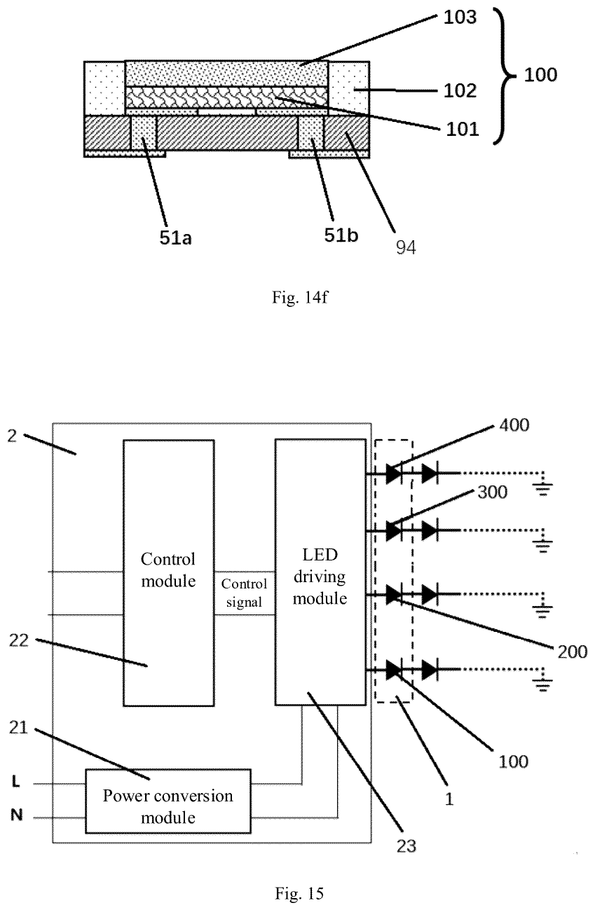

In the example of FIG. 1, an encapsulation structure of the light source module 1 is shown, in which the four light-emitting units are encapsulated as an integral body. In other examples, each light-emitting unit may be independently encapsulated, and finally arranged on the same substrate to form the light source module 1. Alternatively, the first light-emitting unit 100 and the second light-emitting unit 200 may be encapsulated together, while the third light-emitting unit 300 and the fourth light-emitting unit are independently encapsulated, and the present disclosure does not limit this. Independent encapsulation may adopt various encapsulation structures. Because the first light-emitting unit 100, the second light-emitting unit 200, and the third light-emitting unit 300 have the same structure, we take a light-emitting unit with a structure similar to them, the first light-emitting unit 100, as an example to illustrate some other independent encapsulation forms. The first light-emitting unit 100 likewise includes the first light-emitting source 101 and the first encapsulation body 102 covering thereon, as well as the first phosphor body 103. The encapsulation structures of the examples of FIG. 14a and FIG. 14b also adopt a bracket structure as in the example of FIG. 1, with the first receiving groove 61 formed on the bracket. The example of FIG. 14a shows a single light-emitting unit in the light source module 1. After the first light-emitting source 101 is placed, it is electrically connected to the outside through the pins (51a, 51b). The first phosphor body 103 is first spread on the surface of the first light-emitting source 101 by spraying or coating, and then the first encapsulation body 102 is used to fill the first receiving groove 61. In FIG. 14b, the first receiving groove 61 in which the first light-emitting source 101 has been placed is first filled with the first encapsulation body 102, and then the first phosphor body 103 is spread on the upper surface of the first encapsulation body 102 by spraying or coating. As mentioned earlier, it is already known that the first phosphor body 103 of the first light-emitting unit 100 includes multiple different phosphors. The encapsulation structure of FIG. 14c differs from that of FIG. 14b in that different types of phosphors are coated in layers, thereby forming a double-layer structure as shown in the figure. FIG. 14d shows a ceramic high-power encapsulation method, in which ceramic or metal material is used as the substrate 94, the first light-emitting source 101 is disposed on the substrate 94, the first phosphor body 103 is used to form a light conversion layer on the surface of the first light-emitting source 101 by spraying, phosphor film lamination, or phosphor ceramic sheet bonding, and then the filling and covering of the first phosphor body 103 and the first light-emitting source 101 by the first encapsulation body 102 is completed by injection molding. FIG. 14e is a CSP encapsulation, suitable for a high-power chip, in which ceramic or metal material is used as the substrate 94. After the first phosphor body 103 and the first encapsulation body 102 are mixed, the light conversion layer on the surface of the first light-emitting source 101 is formed by phosphor film lamination to complete the encapsulation. The structure of FIG. 14f is similar to that of FIG. 14e, in which ceramic or metal material is likewise used as the substrate 94. The first phosphor body 103 is used to form the light conversion layer on the surface of the first light-emitting source 101 by spraying or phosphor film lamination, and the first encapsulation body 102 is disposed on the outside thereof to complete the encapsulation. All of the above methods can achieve the purpose of the present disclosure, and the present disclosure is not limited thereto.

Another example of the light source module of the present disclosure is as illustrated by FIG. 17, including a light source board 6 and four light-emitting units disposed on the light source board, namely, the first light-emitting unit 100, the second light-emitting unit 200, the third light-emitting unit 300, and the fourth light-emitting unit 400, as well as four lenses in one-to-one correspondence with these light-emitting units, namely, the first lens 501, the second lens 502, the third lens 503, and the fourth lens 504. The first lens 501, the second lens 502, the third lens 503, and the fourth lens 504 respectively cover the first light-emitting unit 100, the second light-emitting unit 200, the third light-emitting unit 300, and the fourth light-emitting unit 400. The spectrum and light colors of the four light-emitting units are the same as those in the foregoing example and will not be repeated here.

In this example, the first lens 501, the second lens 502, the third lens 503, and the fourth lens 504 are integrated into one light distribution module 5. The fourth lens 504 is disposed in the middle, and the other three lenses are disposed around the fourth lens 504. The centers of the first lens 501, the second lens 502, and the third lens 503 are uniformly distributed, that is, distributed at equal angles on a circumferential surface coaxial with the fourth lens.

Another example of the present disclosure is a lighting system as illustrated by FIG. 15, including the light source module 1 and the driving circuit 2 in the foregoing examples.

The driving circuit 2 includes a power conversion module 21, a control module 22, and an LED driving module 23. The power conversion module 21 is connected to an external power supply and converts the external power supply into the direct current power required by the light source module 1. The control module 22 includes a communication module that receives dimming and color tuning commands transmitted from the outside and generates control signals accordingly. The communication module may be a wired or wireless communication module, and the present disclosure is not limited thereto. The input of the LED driving module 23 is the direct current power output by the power conversion module 21 and the control signal transmitted from the control module 22. According to the control signal, the direct current power is regulated by the LED driving module 23, and the driving current/voltage required by each light-emitting unit after regulation is output by the LED driving module 23 respectively to the first light-emitting unit 100, the second light-emitting unit 200, the third light-emitting unit 300, and the fourth light-emitting unit 400 in the light source module 1. Therefore, the LED driving module 23 needs to be electrically connected to the first light-emitting unit 100, the second light-emitting unit 200, the third light-emitting unit 300, and the fourth light-emitting unit 400 respectively. In response to that the lighting system includes a plurality of light source modules 1, as illustrated by FIG. 15, the first light-emitting unit 100, the second light-emitting unit 200, the third light-emitting unit 300, and the fourth light-emitting unit 400 in each light source module 1 are respectively connected in series and then electrically connected to the LED driving module 23.

As mentioned above, the adjustable color temperature range of the light source module 1 in the example is from 1800K to 14000K, and the target spectrum needs to be simulated. Therefore, the control module 22 includes a storage module, in which preset control parameter values are stored. The control parameter values are the control parameter values corresponding to the first light-emitting unit 100, the second light-emitting unit 200, and the third light-emitting unit 300 in response to that the light source module 1 generates different color temperatures. The control parameter values may be voltage values, current values, or PWM signals. In response to that a light-emitting unit does not participate in light mixing, the control parameter value of that light-emitting unit is zero. In response to that an external color temperature change request is sent, the control module 22 receives the command, reads the relevant values from the storage module, forms control signals, and sends them to the LED driving module 23 to regulate the current and voltage output to the first light-emitting unit 100, the second light-emitting unit 200, and the third light-emitting unit 300, so that the light source module 1 emits light of the target color or white light of the corresponding color temperature. In this example, the preset control parameters are the duty ratios of the PWM signals of the light-emitting units as shown in Table 1 and Table 2.

Because the light source module 1 selects light-emitting units of specific colors and is controlled according to our preset parameters, the obtained full-spectrum white light has a wider color temperature coverage range compared to the white light obtained by mixing light in the prior art, and can be achieved from 1800K to 20000K, and the color deviation Duv from the blackbody radiation line is less than 0.003, ensuring that the light color of the entire light source module is more pure under any color temperature state. At the same time, the obtained white light spectrum has a high degree of spectral similarity with the target spectrum. In response to that the color temperature of the white light emitted by the light source module is 2300K to 20000K, the spectral similarity is greater than 85%, and in response to that the color temperature of the white light is 3000K to 10000K, the spectral similarity is greater than 90%. Basically, in the adjustable color temperature range of the light source module, the white light spectrum reaches the level of full-spectrum. In terms of color rendering, also due to its high spectral similarity, in response to that the color temperature of the white light emitted by the light source module is 1800K to 20000K, the color rendering index CRI is greater than 95, and in response to that the color temperature of the white light is 2300K to 10000K, the color rendering index CRI is greater than 97, with R1 to R15 all being greater than 90, the color fidelity Rf based on the TM-30 standard is greater than 95, and the color gamut Rg is from 98 to 102. In summary, the light source module 1 simultaneously has the advantages of a wide color temperature range, high spectral similarity, and good color rendering performance.

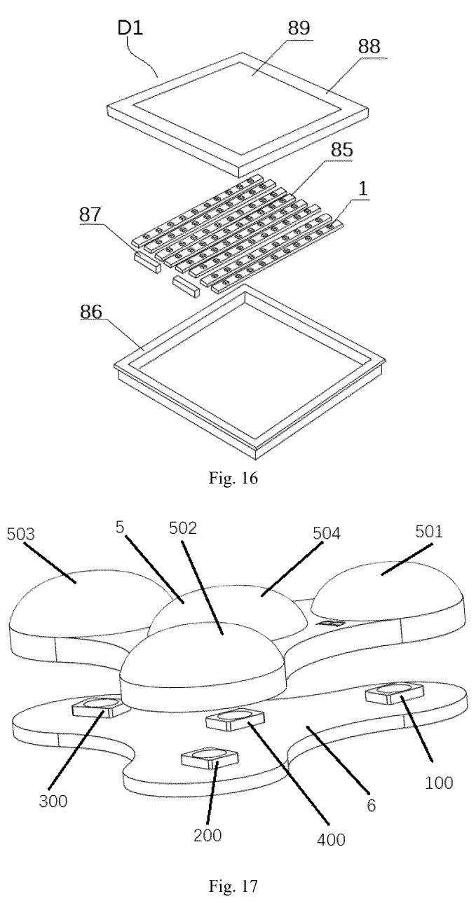

The above light source module and lighting system can be applied to various types of lighting fixtures. FIG. 16 shows a lighting fixture D1 according to an example of the present disclosure. The lighting fixture D1 is a panel light, including the lighting system as described above. In other examples, it may also be a pendant light, a ceiling light, etc., or the light source module 1 may also be used as a general white light chip in various lighting fixtures such as a desk lamp, a downlight, and a spotlight. The lighting fixture D1 includes a chassis 86, a front frame 88 provided with a diffusion plate 89, a plurality of light source modules 1 disposed on a light source board 85, and a power supply box 87, the foregoing driving circuit 2 is disposed in the power supply box 87. In the lighting fixture, the first light-emitting unit 100, the second light-emitting unit 200, the third light-emitting unit 300, and the fourth light-emitting unit 400 in the light source module 1 are respectively wired, and the same type of light-emitting units in each light source module 1 are connected in series with each other and then connected to the driving circuit 2 in the power supply box 87, thereby forming the foregoing lighting system. The lighting fixture D1 may also be equipped with a controller, a heat dissipation device, and a light distribution component according to the specific functions and requirements of the lighting fixture. The controller may be used to adjust the light color, light intensity, etc. of the illumination light emitted by the light source module L1. The light distribution component, in addition to the diffusion plate in the example, may also be a lampshade, a lens, a diffusion element, a light guide, etc. The present disclosure is not limited thereto.

The purpose of the present disclosure is to provide a multi-color light source module, a lighting system and a lighting fixture that have adjustable color temperature of the white light and can achieve full-spectrum white light, so as to solve the above problems.

In order to achieve the above purpose, the technical scheme adopted by the present disclosure is to provide a light source module, which includes: a first light-emitting unit, a second light-emitting unit, a third light-emitting unit, and a fourth light-emitting unit which are electrically independent of each other; the first light-emitting unit includes a first light-emitting source, and a first encapsulation body and a first phosphor body, the first encapsulation body and the first phosphor body cover the first light-emitting source, light emitted by the first light-emitting unit includes at least two spectral emission peaks, a first peak wavelength is located at 445 nm to 460 nm, a second peak wavelength is located at 480 nm to 520 nm, and a spectral intensity at the second peak wavelength is 100% 150% of a spectral intensity at the first peak wavelength, and a light color of the light emitted by the first light-emitting unit is blue-green light located within a quadrilateral region defined by four points A1(0.18, 0.39), A2(0.22, 0.44), A3(0.25, 0.39), and A4(0.22, 0.35) on a 1931-CIE chromaticity diagram; the second light-emitting unit includes a second light-emitting source, a second encapsulation body and a second phosphor body, the second encapsulation body and the second phosphor body cover the second light-emitting source, light emitted by the second light-emitting unit includes at least two spectral emission peaks, a first peak wavelength is located at 585 nm to 620 nm, a second peak wavelength is located at 550 nm to 580 nm, a spectral intensity at the second peak wavelength is 40% to 70% of a spectral intensity at the first peak wavelength, a spectral half-width is 80 nm to 120 nm, and a light color of the light emitted by the second light-emitting unit is yellow-orange light located within a quadrilateral region defined by four points B1(0.46, 0.47), B2(0.48, 0.51), B3(0.53, 0.46), and B4(0.49, 0.44) on the 1931-CIE chromaticity diagram; the third light-emitting unit includes a third light-emitting source, a third encapsulation body and a third phosphor body, the third encapsulation body and the third phosphor body cover the third light-emitting source, light emitted by the third light-emitting unit includes at least two spectral emission peaks, a first peak wavelength is located at 630 nm to 680 nm, a second peak wavelength is located at 550 nm to 580 nm, a spectral intensity at the second peak wavelength is 0 to 40% of a spectral intensity at the first peak wavelength, a spectral half-width is 70 nm to 100 nm, and a light color of the light emitted by the third light-emitting unit is orange-red light located within a quadrilateral region defined by four points C1(0.60, 0.36), C2(0.63, 0.37), C3(0.71, 0.29), and C4(0.67, 0.29) on the 1931-CIE chromaticity diagram; the fourth light-emitting unit includes a fourth light-emitting source and a fourth encapsulation body that covers the fourth light-emitting source, light emitted by the fourth light-emitting unit includes at least two spectral emission peaks, a first peak wavelength is located at 430 nm to 445 nm, a second peak wavelength is located at 460 nm to 480 nm, and a spectral intensity at the second peak wavelength is 40% to 80% of a spectral intensity at the first peak wavelength.

The present disclosure further provides a lighting system, which includes: a light source and a driving circuit, where the light source includes at least one of the above-mentioned light source modules; the driving circuit is electrically connected to and supplies power to the first light-emitting unit, the second light-emitting unit, the third light-emitting unit, and the fourth light-emitting unit, respectively, and the driving circuit respectively controls the current/voltage provided to the first light-emitting unit, the second light-emitting unit, the third light-emitting unit, and the fourth light-emitting unit.

The present disclosure further provides a lighting fixture, which includes the light source module or the lighting system mentioned above.

For the light source module, the lighting system and the lighting fixture provided by the present disclosure, the light source module includes a first light-emitting unit, a second light-emitting unit, a third light-emitting unit, and a fourth light-emitting unit which are electrically independent of each other, and the light emitted by each light-emitting unit is mixed to form white light. Through the selection of the light color and spectral characteristics of the light-emitting units, the white light obtained by mixing light of the light source module has a wide color temperature coverage range, covering a range from 1800K to 20000K, and the corresponding white light color point distribution trajectory can completely follow the blackbody radiation line, with a color deviation Duv value less than 0.003, thereby improving the white light color deviation problem. At the same time, the white light spectrum of the light source module simulates a target spectrum: in response to that the correlated color temperature is above 4000K, the target spectrum is the daylight spectrum; and in response to that the correlated color temperature is below 4000K, the target spectrum is the blackbody radiation spectrum. Because the spectrum simulates the daylight or blackbody radiation spectrum, the white light spectrum obtained has good spectral similarity and color rendering.

The spectral similarity can reach above 85% in the color temperature range of 2300K to 20000K, and can reach above 90% in the color temperature range of 3000 K to 10000K. Within the overall color temperature range from 1800K to 20000K, the white light color rendering index can reach greater than 95; among them, in the range of 2300K to 10000K, the white light color rendering index can reach greater than 97, and R1 to R15 are all greater than 90, the color fidelity Rf based on the TM-30 standard is greater than 95, and the color gamut Rg is 98 to 102. The white light color of this module is closer to daylight, significantly superior to the light quality performance of existing dual color temperature white light sources, and is more suitable for the general lighting field.

The present disclosure may include dedicated hardware implementations such as disclosure specific integrated circuits, programmable logic arrays and other hardware devices. The hardware implementations can be constructed to implement one or more of the methods described herein. Examples that may include the apparatus and systems of various implementations can broadly include a variety of electronic and computing systems. One or more examples described herein may implement functions using two or more specific interconnected hardware modules or devices with related control and data signals that can be communicated between and through the modules, or as portions of an disclosure-specific integrated circuit. Accordingly, the system disclosed may encompass software, firmware, and hardware implementations. The terms “module,” “sub-module,” “circuit,” “sub-circuit,” “circuitry,” “sub-circuitry,” “unit,” or “sub-unit” may include memory (shared, dedicated, or group) that stores code or instructions that can be executed by one or more processors. The module refers herein may include one or more circuit with or without stored code or instructions. The module or circuit may include one or more components that are connected.

The above description of the examples of the present disclosure is for the purpose of illustration and description, and is not intended to be exhaustive or to limit the present disclosure to the specific forms disclosed.

1. A light source module, comprising: a first light-emitting unit, a second light-emitting unit, a third light-emitting unit, and a fourth light-emitting unit that are electrically independent of each other;
wherein the first light-emitting unit comprises a first light-emitting source, a first encapsulation body and a first phosphor body, the first encapsulation body and the first phosphor body cover the first light-emitting source; light emitted by the first light-emitting unit comprises at least two spectral emission peaks, a first peak wavelength is located at 445 nm to 460 nm, a second peak wavelength is located at 480 nm to 520 nm, and a spectral intensity at the second peak wavelength is 100% to 150% of a spectral intensity at the first peak wavelength; and a light color of the light emitted by the first light-emitting unit is blue-green light located within a quadrilateral region defined by four points A1(0.18, 0.39), A2(0.22, 0.44), A3(0.25, 0.39), and A4(0.22, 0.35) on a 1931-CIE chromaticity diagram;
the second light-emitting unit comprises a second light-emitting source, a second encapsulation body, and a second phosphor body, the second encapsulation body and the second phosphor body cover the second light-emitting source; light emitted by the second light-emitting unit comprises at least two spectral emission peaks, a first peak wavelength is located at 585 nm to 620 nm, a second peak wavelength is located at 550 nm to 580 nm, and a spectral intensity at the second peak wavelength is 40% to 70% of a spectral intensity at the first peak wavelength, a spectral half-width is 80 nm to 120 nm; a light color is yellow-orange light located within a quadrilateral region defined by four points B1(0.46, 0.47), B2(0.48, 0.51), B3(0.53, 0.46), and B4(0.49, 0.44) on the 1931-CIE chromaticity diagram;
the third light-emitting unit comprises a third light-emitting source, a third encapsulation body, and a third phosphor body, the third encapsulation body and the third phosphor body cover the third light-emitting source; light emitted by the third light-emitting unit comprises at least two spectral emission peaks, a first peak wavelength is located at 630 nm to 680 nm, a second peak wavelength is located at 550 nm to 580 nm, and a spectral intensity at the second peak wavelength is 0 to 40% of a spectral intensity at the first peak wavelength, a spectral half-width is 70 nm to 100 nm; a light color is orange-red light located within a quadrilateral region defined by four points C1(0.60, 0.36), C2(0.63, 0.37), C3(0.71, 0.29), and C4(0.67, 0.29) on the 1931-CIE chromaticity diagram;
the fourth light-emitting unit comprises a fourth light-emitting source and a fourth encapsulation body covering the fourth light-emitting source; light emitted by the fourth light-emitting unit comprises at least two spectral emission peaks, a first peak wavelength is located at 430 nm to 445 nm, a second peak wavelength is located at 460 nm to 480 nm, and a spectral intensity at the second peak wavelength is 40% to 80% of a spectral intensity at the first peak wavelength.

2. The light source module according to claim 1, wherein a blue light proportion of the second light-emitting unit is less than 10%, and a blue light proportion of the third light-emitting unit is less than 5%.

3. The light source module according to claim 1, wherein the fourth light-emitting source is an LED chip combination comprising two or more blue LED chips with different peak wavelengths, and the peak wavelength of the blue LED chips is 430 nm to 475 nm, and a peak wavelength difference between any two of the two or more blue LED chips with different peak wavelengths is greater than or equal to 10 nm.

4. The light source module according to claim 3, wherein a peak wavelength of a first blue LED chip is 430 nm to 445 nm; a peak wavelength of a second blue LED chip is 445 nm to 460 nm; a peak wavelength of a third blue LED chip is 460 nm to 475 nm, a peak wavelength difference between any two of the first blue LED chip, the second blue LED chip, and the third blue LED chip is greater than or equal to 10 nm, the fourth light-emitting source comprises the first blue LED chip and the third blue LED chip, and the first light-emitting source, the second light-emitting source, and the third light-emitting source each is the second blue LED chip.

5. The light source module according to claim 1, wherein the first phosphor body comprises at least one blue-green phosphor having a peak wavelength located at 485 nm to 515 nm and at least one yellow-green phosphor having a peak wavelength located at 500 nm to 580 nm, the blue-green phosphor comprises (Ba, Sr)Si₂N₂O₂:Eu; the yellow-green phosphor comprises (Lu, Yb, Tb)₃(Al, Ga)₅O₁₂:Ce, Ga—Y₃Al₅O₁₂:Ce, or Y₃(Al, Ga)₅O₁₂:Ce; a red phosphor comprises CaAlSiN₃:Eu, (Ca, Sr)AlSiN₃:Eu, (Ba, Sr, Ca, Mg)₂Si₅N₈:Eu, K₂SiF₆:Mn⁴⁺, K₂GeF₆:Mn⁴⁺, or K₂TiF₆:Mn⁴⁺.

6. The light source module according to claim 1, wherein the second phosphor body comprises at least one yellow phosphor having a peak wavelength located at 550 nm to 580 nm and at least one red/orange phosphor having a peak wavelength located at 580 nm to 620 nm, the yellow phosphor is (Lu, Yb, Tb)₃(Al, Ga)₅O₁₂:Ce, Ga—Y₃Al₅O₁₂:Ce, or Y₃(Al, Ga)₅O₁₂:Ce; the red/orange phosphor is CaAlSiN₃:Eu, (Ca, Sr)AlSiN₃:Eu, (Ba, Sr, Ca, Mg)₂Si₅N₈:Eu, K₂SiF₆:Mn⁴⁺, K₂GeF₆:Mn⁴⁺, or K₂TiF₆:Mn⁴⁺.

7. The light source module according to claim 1, wherein the third phosphor body comprises at least one yellow-green phosphor having a peak wavelength located at 520 nm to 580 nm and at least one red phosphor having a peak wavelength located at 630 nm to 680 nm, the yellow-green phosphor is (Lu, Yb, Tb)₃(Al, Ga)₅O₁₂:Ce, Ga—Y₃Al₅O₁₂:Ce, or Y₃(Al, Ga)₅O₁₂:Ce; the red phosphor is CaAlSiN₃:Eu, (Ca, Sr)AlSiN₃:Eu, (Ba, Sr, Ca, Mg)₂Si₅N₈:Eu, K₂SiF₆:Mn⁴⁺, K₂GeF₆:Mn⁴⁺, or K₂TiF₆:Mn⁴⁺.

8. The light source module according to claim 1, wherein white light formed by mixing light emitted from the first light-emitting unit, light emitted by the second light-emitting unit, light emitted by the third light-emitting unit, and light emitted by the fourth light-emitting unit has a correlated color temperature adjustable within a range of 1800K to 20000K, and a color deviation Duv from a blackbody radiation line is less than 0.003, and a color rendering index (CRI) is greater than 95.

9. The light source module according to claim 8, wherein the white light formed by mixing the light emitted by the first light-emitting unit, the light emitted by the second light-emitting unit, the light emitted by the third light-emitting unit, and the light emitted by the fourth light-emitting unit has a color rendering index (CRI) greater than 97 with a correlated color temperature within a range of 2300K to 10000 K, wherein R1 to R15 are all greater than 90, and a color fidelity Rf based on a TM-30 standard is greater than 95, and a color gamut Rg is from 98 to 102.

10. The light source module according to claim 8, wherein in response to that the white light formed by mixing the light emitted by the first light-emitting unit, the light emitted by the second light-emitting unit, the light emitted by the third light-emitting unit, and the light emitted by the fourth light-emitting unit simulates a target spectrum, and a spectral similarity with the target spectrum within the correlated color temperature within a range of 2300K to 20000 K is greater than 85%, wherein when the correlated color temperature is above 4000K, the target spectrum is a daylight spectrum; and when the correlated color temperature is below 4000K, the target spectrum is a blackbody radiation spectrum.

11. The light source module according to claim 10, wherein in response to that the white light formed by mixing the light emitted by the first light-emitting unit, the light emitted by the second light-emitting unit, the light emitted by the third light-emitting unit, and the light emitted by the fourth light-emitting unit simulates the target spectrum, the spectral similarity with the target spectrum within the correlated color temperature within a range of 3000K to 10000K is greater than 90%.

12. The light source module according to claim 1, wherein the light source module is an encapsulated chip comprising a main body, the main body is provided with a first receiving groove, a second receiving groove, a third receiving groove, and a fourth receiving groove, the first light-emitting source and the first phosphor body are disposed in the first receiving groove, the second light-emitting source and the second phosphor body are disposed in the second receiving groove, the third light-emitting source and the third phosphor body are disposed in the third receiving groove, the fourth light-emitting source is disposed in the fourth receiving groove, the first encapsulation body, the second encapsulation body, the third encapsulation body, and the fourth encapsulation body respectively fill the first receiving groove, the second receiving groove, the third receiving groove, and the fourth receiving groove, and the first encapsulation body, the second encapsulation body, the third encapsulation body, and the fourth encapsulation body respectively cover the first light-emitting source, the second light-emitting source, the third light-emitting source, and the fourth light-emitting source.

13. The light source module according to claim 1, wherein the light source module comprises a light source board, the first light-emitting unit, the second light-emitting unit, the third light-emitting unit, and the fourth light-emitting unit are disposed on the light source board, a first lens, a second lens, a third lens, and a fourth lens respectively cover the first light-emitting unit, the second light-emitting unit, the third light-emitting unit, and the fourth light-emitting unit, the first lens, the second lens, the third lens, and the fourth lens are rotational lenses, and the first lens, the second lens, and the third lens are uniformly distributed along a circumference around the fourth lens.

14. A lighting system, comprising: a light source and a driving circuit,
the light source comprises at least one light source module according to claim 1;
the driving circuit is electrically connected to and supplies power to the first light-emitting unit, the second light-emitting unit, the third light-emitting unit, and the fourth light-emitting unit, respectively, and the driving circuit respectively controls the current/voltage provided to the first light-emitting unit, the second light-emitting unit, the third light-emitting unit, and the fourth light-emitting unit.

15. A lighting fixture, comprising the light source module according to claim 1.

16. A lighting fixture, comprising the lighting system according to claim 14.
